(19) United States
(12) Patent Application Publication
(10) Pub. No.: US 2006/0067117 A1
(43) Pub. Date: Mar. 30, 2006

(54) Fuse memory cell comprising a diode, the diode serving as the fuse element

(75) Inventor: Christopher J. Petti, Mountain View, CA (US)

Correspondence Address: MATRIX SEMICONDUCTOR, INC., 3230 SCOTT BOULEVARD, SANTA CLARA, CA, 95054, US

(73) Assignee: Matrix Semiconductor, Inc., Santa Clara, CA (US)

(21) Appl. No.: 10/955,387

(22) Filed: Sep. 29, 2004

(51) Int. Cl. G11C 17/18; G11C 11/36

(52) U.S. Cl. 365/175; 365/225.7

(57) ABSTRACT

A memory cell is formed of a semiconductor junction diode interposed between conductors. The cell is programmed by rendering the memory cell very high-resistance, such that current no longer flows between the conductors on application of a read voltage. In this cell the diode behaves as a fuse. The semiconductor junction diode comprises silicon, the silicon crystallized in contact with a silicide. The silicide may provide a template for crystallization, decreasing the defect density of the silicon and improving its conductivity. It is advantageous to reduce a dielectric layer (such as an oxide, nitride, or oxynitride) intervening between the silicon and the silicon-forming metal during the step of forming the silicide.

### RELATED APPLICATIONS

This application is related to Herner et al., U.S. application Ser. No. ______, “Junction Diode Comprising Varying Semiconductor Compositions,” (attorney docket number MA-121); to Herner et al., U.S. application Ser. No. ______, “Nonvolatile Memory Cell Without a Dielectric Antifuse Having High- and Low-Impedance States,” (attorney docket number MA-086-a-1), hereinafter the ______ application; and to Herner, U.S. application Ser. No. ______, “Memory Cell Comprising a Semiconductor Junction Diode Crystallized Adjacent to a Silicide,” (attorney docket number MA-109-1), hereinafter the ______ application; all assigned to the assignee of the present invention, all filed on even date herewith and all hereby incorporated by reference in their entirety.

### BACKGROUND OF THE INVENTION

The invention relates to a fuse memory cell comprising a low-impedance diode programmed by converting the diode to a high-impedance state.

Nonvolatile memory cells are known which employ a vertically oriented diode interposed between conductors, the diode paired with an antifuse, or having an antifuse interposed between diode portions. As formed, the cell conducts little or no current when a read voltage is applied. The cell is programmed by applying a high voltage between the conductors, across the diode and antifuse, rupturing the antifuse and creating a low-impedance path across the cell such that increased current flows between the conductors when the same read voltage is applied.

In general, in semiconductor applications, it is advantageous to increase density, packing more devices into a smaller die area. As a memory cell pairing a diode with an antifuse is fabricated with increasingly small dimensions, the window between the energy required to program the cell and an energy sufficient to destroy the cell decreases.

There is a need, therefore, for a nonvolatile one-time programmable memory cell that can be scaled to very small dimensions while remaining easily programmable.

### SUMMARY OF THE PREFERRED EMBODIMENTS

The present invention is defined by the following claims, and nothing in this section should be taken as a limitation on those claims. In general, the invention is directed to a fuse memory cell comprising a diode formed in an unprogrammed, low-impedance state which is converted to a programmed, high-impedance state, the diode itself acting as the fuse.

A first aspect of the invention provides for a nonvolatile fuse memory cell having an unprogrammed and a programmed state, comprising a semiconductor junction diode, wherein the semiconductor junction diode operates as a fuse when the cell is converted from the unprogrammed state to the programmed state.

Another aspect of the invention provides for a plurality of unprogrammed nonvolatile fuse memory cells comprising a plurality of substantially parallel first conductors formed at a first height above a substrate; a plurality of substantially parallel second conductors formed at a second height above the substrate, wherein the second height is different from the first height; a plurality of conductive pillars, each pillar disposed between one of the first conductors and one of the second conductors, and each pillar in electrical contact with one of the first pillars and one of the second pillars, wherein each pillar comprises a silicide layer.

A preferred embodiment of the invention provides for a monolithic three dimensional memory array of memory cells, the array comprising: a first memory level, the first memory level comprising a first plurality of memory cells, each memory cell of the first plurality having an unprogrammed and a programmed state, each memory cell comprising a semiconductor junction diode, wherein the semiconductor junction diode operates as a fuse when the cell is converted from the unprogrammed state to the programmed state; and a second memory level, the second memory level monolithically formed above the first.

Another preferred embodiment provides for a monolithic three dimensional memory array comprising: a first memory level formed above a substrate, the first memory level comprising: a plurality of substantially parallel lower conductors formed at a first height above the substrate; a plurality of substantially parallel upper conductors formed at a second height above the substrate, wherein the second height is above the first height; and a plurality of pillars, each pillar disposed between one of the first conductors and one of the second conductors, wherein each pillar comprises a junction diode and a silicide layer, wherein each junction diode is in electrical contact with one of the lower conductors and one of the upper conductors; and a second memory level monolithically formed above the first.

Another aspect of the invention provides for a method for forming and programming a fuse memory cell, the method comprising: forming a memory cell, the memory cell comprising a semiconductor junction diode having an unprogrammed, low-impedance state; and programming the memory cell by converting the diode to a programmed, high-impedance state.

Yet another aspect of the invention provides for a method for forming a plurality of unprogrammed fuse memory cells, the method comprising: forming a plurality of substantially parallel first conductors at a first height above a substrate; forming a plurality of first semiconductor junction diodes, each first semiconductor junction diode on and in electrical contact with one of the first conductors; forming a silicide layer on and in contact with each of the first semiconductor junction diodes; and forming a plurality of substantially parallel second conductors at a second height above the substrate, each silicide layer in electrical contact with one of the second conductors.

Another preferred embodiment of the invention provides for a method for forming a monolithic three dimensional memory array, the method comprising: forming a first memory level of memory cells by a method comprising: forming a plurality of substantially parallel lower conductors at a first height above a substrate; forming a plurality of substantially parallel upper conductors at a second height above the substrate, the second height above the first; and forming a plurality of pillars, each pillar disposed between and in electrical contact with one of the first conductors and one of the second conductors, wherein each pillar comprises a silicide layer; and monolithically forming a second memory level above the first.

Each of the aspects and embodiments of the invention described herein can be used alone or in combination with one another.

The preferred aspects and embodiments will now be described with reference to the attached drawings.

### BRIEF DESCRIPTION OF THE DRAWINGS

FIGS. 1a and 1b are perspective views of the same memory cell comprising a junction diode and an antifuse between conductors formed at different feature sizes.

FIGS. 2a-2d are cross-sectional views illustrating fabrication of a plurality of memory cells formed according to the present invention.

FIGS. 3a and 3b are cross-sectional views showing preferred configurations of p-i-n junction diodes to be used in the memory cell of the present invention.

FIG. 4 is a perspective view of a memory cell comprising a vertically oriented junction diode having no dielectric rupture antifuse disposed between top and bottom conductors.

FIG. 5 is a plan view of one possible circuit layout for a memory comprising cells formed according to the present invention.

FIGS. 6a and 6b are plan views of steps in the formation and preconditioning of a memory level comprising both fuse and non-fuse memory cells.

### DETAILED DESCRIPTION OF THE PREFERRED EMBODIMENTS

A semiconductor junction diode, for example a p-n diode or a p-i-n diode, has been paired with a dielectric rupture antifuse to form a memory cell. The diode is interposed between conductors, and a programming voltage is applied between the conductors to rupture the antifuse and program the memory cell. Examples include the memory cells and memory arrays described in Herner et al., U.S. patent application Ser. No. 10/326,470, “An Improved Method for Making High Density Nonvolatile Memory,” filed Dec. 19, 2002 and hereinafter the '470 application; Johnson et al., U.S. Pat. No. 6,034,882, “Vertically stacked field programmable nonvolatile memory and method of fabrication,” and hereinafter the '882 patent; Johnson, U.S. Pat. No. 6,525,953, “Vertically stacked field programmable nonvolatile memory and method of fabrication”; Knall et al., U.S. Pat. No. 6,420,215, “Three Dimensional Memory Array and Method of Fabrication”; Vyvoda et al., U.S. patent application Ser. No. 10/185507, “Electrically Isolated Pillars in Active Devices,” filed Jun. 27, 2002; Cleeves et al., “Optimization of Critical Dimensions and Pitch of Patterned Features in and Above a Substrate,” U.S. patent application Ser. No. 10/728,451, filed Dec. 5, 2003; Petti et al., U.S. patent application Ser. No. 10/728230, “Semiconductor Device Including Junction Diode Contacting Contact-Antifuse Unit Comprising Silicide,” filed Dec. 3, 2002, hereinafter the '230 application, all assigned to the assignee of the present invention and all hereby incorporated by reference.

The term junction diode is used herein to refer to a semiconductor device with the property of conducting current more easily in one direction than the other, having two terminal electrodes, and made of semiconducting material which is p-type at one electrode and n-type at the other. Examples include p-n diodes and n-p diodes, which have p-type semiconductor material and n-type semiconductor material in contact, and p-i-n and n-i-p diodes, in which intrinsic (undoped) semiconductor material is interposed between p-type semiconductor material and n-type semiconductor material.

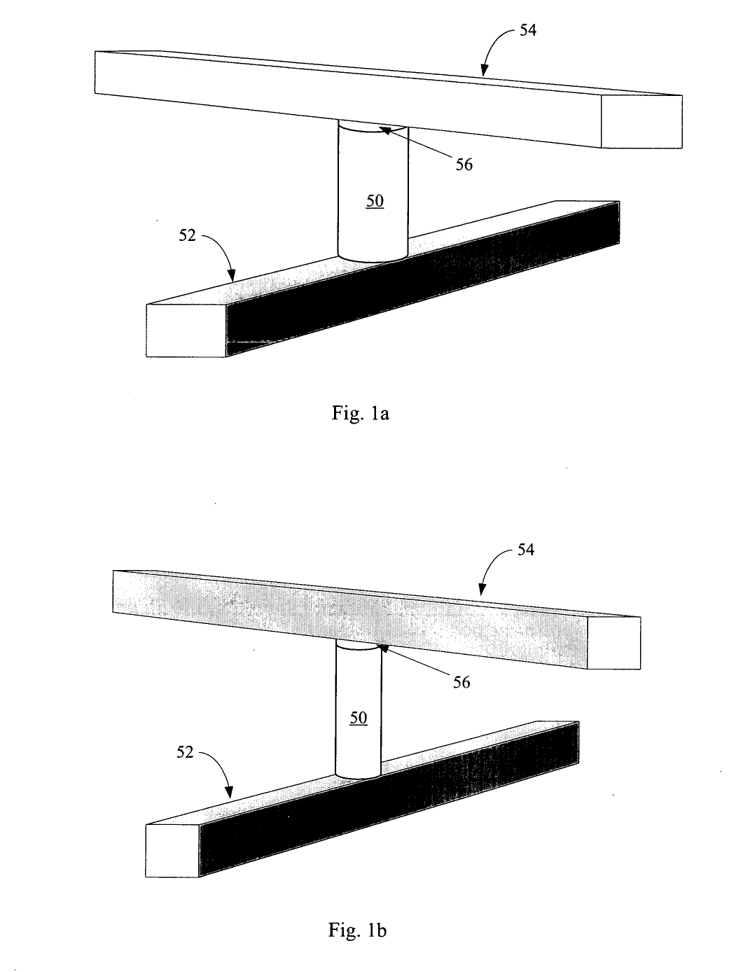

FIG. 1a shows a device having a vertically oriented junction diode 50 disposed between conductors 52 and 54. An antifuse 56 is in series with the diode. FIG. 1b shows the same device formed at a smaller feature size. In general, in a device having a vertically oriented diode, programming the device consists of rupturing the antifuse 56, and then passing sufficient current through the device to form a low-resistance conductive path (or link) through the ruptured antifuse. The current required to program the device and form a low-resistance link remains the same even when feature size is reduced. Thus, for a given programming time, substantially the same current (and thus applied voltage) is required to rupture antifuse 56 for the device of FIG. 1a and for the device of FIG. 1b.

A sufficiently high current, however, will destroy such a diode, for example by melting diode 50 and physically disrupting its contact to conductors 52 or 54 or both. The current which will be destructive to the cell decreases with decreasing feature size of the cell. The cell shown in FIG. 1b will be destroyed or damaged at a lower current than will the cell shown in FIG. 1a. Thus the window between the programming voltage and a voltage which will be destructive to the cell decreases as feature size decreases.

The memory cell of the present invention addresses this difficulty by using flow of a destructive current as the programming event. In the memory cells discussed so far, the unprogrammed cell is in a high-impedance state, and after programming, the programmed cell is in a low-impedance state. In the present invention, these states are reversed: The unprogrammed cell is a diode interposed between conductors, and the cell is in a low-impedance state. After programming, the diode is destroyed or disrupted, and the cell is in a high impedance state.

This memory cell is thus a fuse memory cell, rather than an antifuse memory cell. The memory cell of the '882 patent includes a steering element and a state change element. In most embodiments the steering element is realized as a diode, and in some embodiments of the '882 patent, the steering element is a fuse. Thus the memory cell of the '882 patent may be realized as a diode and a fuse in series. In the present invention, in contrast, the diode itself serves as the fuse element. The resulting memory cell is simpler and easier to fabricate.

The ______ application (attorney docket no. MA-86-a-1) describes a memory cell having a vertically oriented junction diode, interposed between conductors, formed without a dielectric rupture antifuse. It has been found that, despite the absence of an antifuse, this cell is formed in a high-impedance state, and converts to a low-impedance state upon application of a programming voltage. While not wishing to be bound by any particular theory, it may be that application of a programming voltage to this memory cell changes the characteristics of the junction diode, which is typically formed of polycrystalline silicon (polysilicon). One possibility is that the polysilicon of the junction diode is formed in a high-resistance state, and a low-resistance filament is formed through the pillar upon application of a programming voltage.

As taught in the ______ application (attorney docket no. MA-109-1), it has been found that if the junction diode is crystallized while in contact with a silicide, the cell is low-impedance as formed. The silicide may provide a template for crystal growth of the silicon, decreasing the density of silicon defects and improving the conductivity of the silicon. It is particularly advantageous to form the silicide by 1) depositing silicon, 2) forming an oxide, nitride, or oxynitride on the silicon, 3) forming a silicide-forming metal on the oxide, nitride, or oxynitride, then 4) annealing to reduce the oxide, nitride, or oxynitride and form the silicide by reaction of the silicide-forming metal with the silicon.

A first embodiment of the present invention employs this method to form a junction diode which is low-impedance as formed and which is programmed by applying voltage sufficient to destroy or disrupt the diode.

A detailed example will be provided of fabrication of an array of memory cells formed according to aspects of the present invention. For completeness, many details of materials, process conditions, and steps will be provided. It will be understood, however, that many details can be changed, omitted or supplemented while the results fall within the scope of the invention.

### First Embodiment

The '470 application described fabrication of a monolithic three dimensional memory array comprising memory cells like those of FIGS. 1a and 1b. The '230 application described fabrication of a monolithic three dimensional memory array comprising a related memory cell. The methods and procedures taught in those applications, with modifications described in this discussion, can provide guidance in formation of monolithic three dimensional memory arrays in which the memory cells comprise junction diodes. For clarity, not all of the details of the '470 and '230 applications will be included, but it will be understood that no teaching of these applications is intended to be excluded.

Fabrication of a single memory level is described in detail. Additional memory levels can be stacked, each monolithically formed above the one below it.

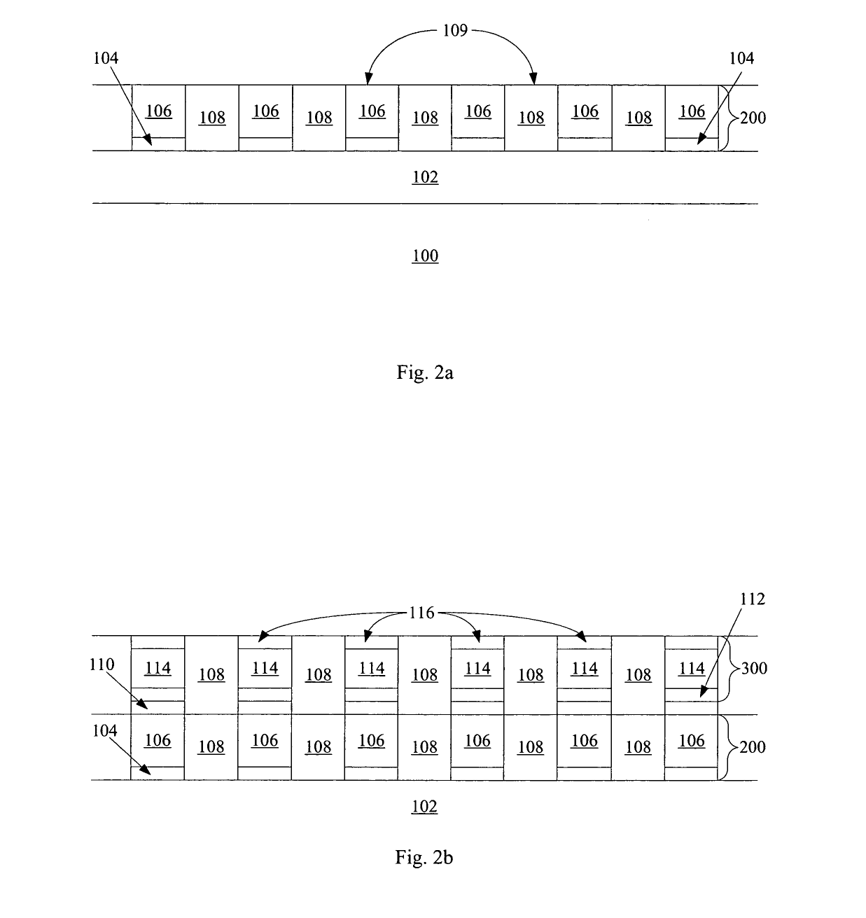

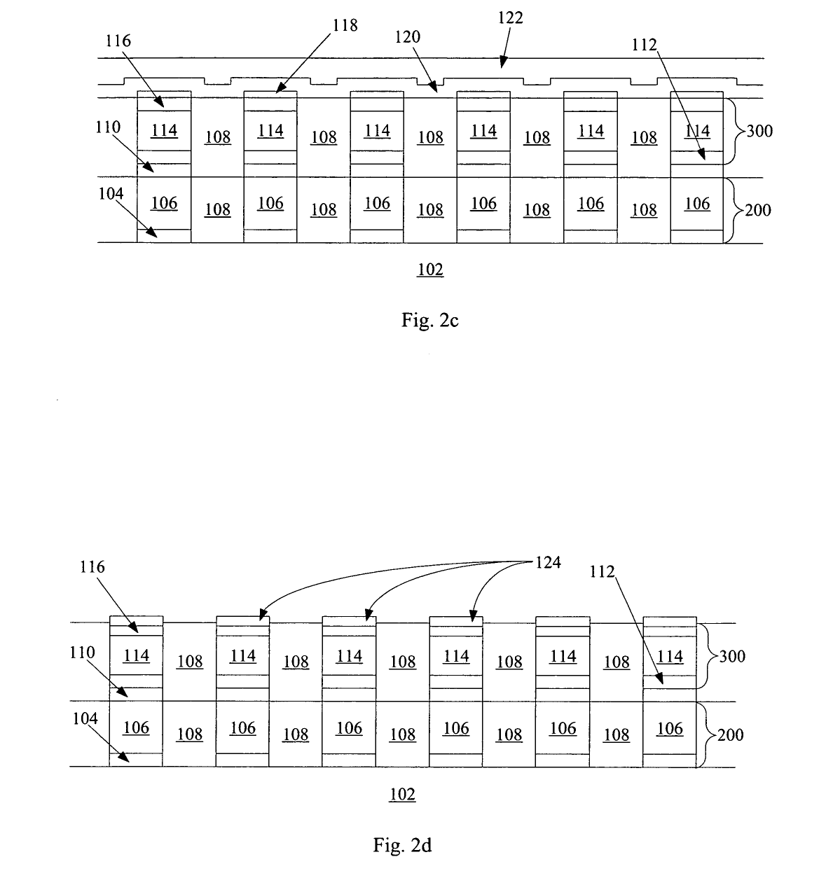

Turning to FIG. 2a, formation of the memory begins with a substrate 100. This substrate 100 can be any semiconducting substrate as known in the art, such as monocrystalline silicon, IV-IV compounds like silicon-germanium or silicon-germanium-carbon, III-V compounds, II-VII compounds, epitaxial layers over such substrates, or any other semiconducting material. The substrate may include integrated circuits fabricated therein.

An insulating layer 102 is formed over substrate 100. The insulating layer 102 can be silicon oxide, silicon nitride, high-dielectric film, Si—C—O—H film, or any other suitable insulating material.

The first conductors 200 are formed over the substrate and insulator. An adhesion layer 104 may be included between the insulating layer 102 and the conducting layer 106 to help the conducting layer 106 adhere. Preferred materials for the adhesion layer 104 are tantalum nitride, tungsten nitride, titanium tungsten, sputtered tungsten, titanium nitride, or combinations of these materials. If the overlying conducting layer is tungsten, titanium nitride is preferred as an adhesion layer.

The next layer to be deposited is conducting layer 106. Conducting layer 106 can comprise any conducting material known in the art, including tantalum, titanium, tungsten, copper, cobalt, or alloys thereof. Titanium nitride may be used.

If tungsten is used for conducting layer 106, it is preferred to use a barrier layer between the tungsten and the semiconductor material that will be part of the semiconductor pillars that will eventually overlie the conductors. Such a barrier layer serves to prevent reaction between tungsten and silicon. The barrier layer may either be patterned with the conductor rails or with the semiconductor pillars.

If a barrier layer is to be used, and is to be formed as the top layer of the conductor rails, the barrier layer should be deposited after the conducting layer 106. (The barrier layer is not shown in FIG. 2a.) Any material serving this function can be used in the barrier layer, including tungsten nitride, tantalum nitride, titanium nitride, or combinations of these materials. In a preferred embodiment, titanium nitride is used as the barrier layer. Where the barrier layer is titanium nitride, it can be deposited in the same manner as the adhesion layer described earlier.

Once all the layers that will form the conductor rails have been deposited, the layers will be patterned and etched using any suitable masking and etching process to form substantially parallel, substantially coplanar conductors 200, shown in FIG. 2a in cross-section. In one embodiment, photoresist is deposited, patterned by photolithography and the layers etched, and then the photoresist removed using standard process techniques.

Next a dielectric material 108 is deposited over and between conductor rails 200. Dielectric material 108 can be any known electrically insulating material, such as silicon oxide, silicon nitride, or silicon oxynitride. In a preferred embodiment, silicon oxide is used as dielectric material 108.

Finally, excess dielectric material 108 on top of conductor rails 200 is removed, exposing the tops of conductor rails 200 separated by dielectric material 108, and leaving a substantially planar surface 109. The resulting structure is shown in FIG. 2a. This removal of dielectric overfill to form planar surface 109 can be performed by any process known in the art, such as chemical mechanical planarization (CMP) or etchback. At this stage, a plurality of substantially parallel first conductors have been formed at a first height above substrate 100.

Next, turning to FIG. 2b, vertical semiconductor pillars will be formed above completed conductor rails 200. (To save space substrate 100 is omitted in FIG. 2b; its presence will be assumed.) If a barrier layer 110 is to be used between the lower conductor rails and the semiconductor elements, and has not yet been formed, it will be deposited as the first layer after planarization of the conductor rails. It can be of any of the materials and deposited in any of the manners described earlier. Its thickness can be, for example, about 20 to about 500 angstroms. The thickness of barrier layer 110 is preferably about 200 angstroms.

Next semiconductor material that will be patterned into pillars is deposited. The semiconductor material can be silicon, silicon-germanium, silicon-germanium-carbon, germanium, or other suitable semiconductors or compounds. Silicon is commonly used in the industry, so, for simplicity, this description will refer to the semiconductor material as silicon, but it will be understood that other materials may be substituted.

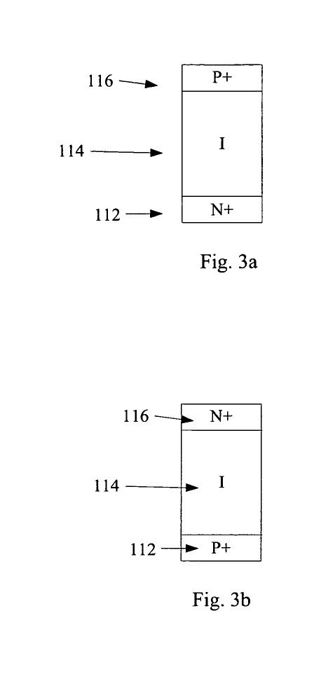

In preferred embodiments, the semiconductor pillar is a junction diode, comprising a bottom heavily doped region of a first conductivity type and a top heavily doped region of a second conductivity type. The middle region, between the top and bottom regions, is an intrinsic or lightly doped region of either the first or second conductivity type. The diode of FIG. 3a has a bottom region 112 of N+ (heavily doped n-type) silicon, intrinsic region 114, and P+ top region 116. The diode of FIG. 3b is reversed, having bottom region 112 of P+ silicon, intrinsic region 114, and N+ top region 116. The middle region is intrinsic, or not intentionally doped, though in some embodiments it may be lightly doped. An undoped region will never be perfectly electrically neutral, and will always have defects or contaminants that cause it to behave as if slightly n-doped or p-doped. Such a diode can be considered a p-i-n diode.

To form, for example, the diode of FIG. 3a, a layer of heavily doped n-type silicon 112 must be formed. This layer can be formed by any deposition and doping method known in the art. The silicon can be deposited and then doped, but is preferably doped in situ by flowing a donor gas providing dopant atoms during deposition of the silicon. In a preferred embodiment, this layer can range from about 100 to about 1000 angstroms, preferably 200 angstroms, and have a dopant concentration of about 1×10¹⁹ to about 2×10²¹ atoms/cm³, and preferably about 8×10²⁰ atoms/cm³.

The next layer 114 will be intrinsic undoped silicon. This layer can formed by any deposition method known in the art. The thickness of the intrinsic silicon layer can range from about 1000 to about 4000 angstroms, preferably about 2500 angstroms. In one embodiment, silicon is deposited without intentional doping, yet has defects which render it slightly n-type.

Above this is a layer 116 of heavily doped p-type silicon. This layer is preferably deposited undoped, and will be doped by ion implantation in a later step. The thickness of heavily doped p-type silicon region 116 can range from about 100 to about 2000 angstroms, preferably about 800 angstroms. Note this is the thickness as-deposited. Some portion of the top of this layer will be consumed in a subsequent CMP or etchback step, and will thus be thinner in the finished device. After implantation, this layer will preferably have a dopant concentration of about 2×10¹⁹ to about 4×10²¹ atoms/cm³, preferably about 8×10²⁰ atoms/cm³.

To summarize, forming the junction diode includes forming a first heavily doped silicon layer of a first conductivity type; forming a second lightly or intrinsically doped silicon layer directly on the first heavily doped layer; and forming a third heavily doped silicon layer of a second conductivity type directly on the second lightly or intrinsically doped silicon layer, the second conductivity type opposite the first.

Returning to FIG. 2b, semiconductor layers 116, 114 and 112 just deposited will be patterned and etched to form semiconductor pillars 300. If barrier layer 110 was not patterned with the bottom conductor rails, it will be patterned with the pillars. Semiconductor pillars 300 should have about the same pitch and about the same width as conductors 200 below, such that each semiconductor pillar 300 is formed on top of a conductor 200. Some misalignment can be tolerated.

The semiconductor pillars 300 can be formed using any suitable masking and etching process. For example, photoresist can be deposited, patterned using standard photolithography techniques, and etched, then the photoresist removed. Alternatively, a hard mask of some other material, for example silicon dioxide, can be formed on top of the semiconductor layer stack, with bottom antireflective coating (BARC) on top, then patterned and etched. Similarly, dielectric antireflective coating (DARC) can be used as a hard mask.

The photolithography techniques described in Chen, U.S. application Ser. No. 10/728436, “Photomask Features with Interior Nonprinting Window Using Alternating Phase Shifting,” filed Dec. 5, 2003; or Chen, U.S. application Ser. No. 10/815312, Photomask Features with Chromeless Nonprinting Phase Shifting Window,” filed Apr. 1, 2004, both owned by the assignee of the present invention and hereby incorporated by reference, can advantageously be used to perform any photolithography step used in formation of a memory array according to the present invention.

The pitch and width of the pillars can be varied as desired. In one preferred embodiment, the pitch of the pillars (the distance from the center of one pillar to the center of the next pillar) is about 300 nm, while the maximum diameter of a pillar, and thus of the junction diode, varies between about 100 and about 150 nm. In another preferred embodiment, the pitch of the pillars is about 260 nm, while the maximum diameter of a pillar varies between about 90 and 130 nm. The maximum diameter of the junction diode may be less than 90 nm, for example about 50 or about 70 nm.

Dielectric material 108 is deposited over and between the semiconductor pillars 300, filling the gaps between them. Dielectric material 108 can be any known electrically insulating material, such as silicon oxide, silicon nitride, or silicon oxynitride. In a preferred embodiment, silicon dioxide is used as the insulating material.

Next the dielectric material on top of the pillars 300 is removed, exposing the tops of pillars 300 separated by dielectric material 108, and leaving a substantially planar surface. This removal of dielectric overfill can be performed by any process known in the art, such as CMP or etchback. The resulting structure is shown in FIG. 2b. The ion implantation of heavily doped top regions 116 should be performed at this point, in this example using a p-type dopant to form a P+ region.

Turning to FIG. 2c, next an oxide, nitride, or oxynitride layer 118 is formed on heavily doped regions 116. In preferred embodiments, as shown, a silicon dioxide layer 118 is grown by oxidizing silicon at the tops of heavily doped regions 116 at about 600 to about 850 degrees C. for about 20 seconds to about two minutes, forming between about 15 and about 50 angstroms of silicon dioxide. Preferably, oxide layer 118 is formed by exposing the wafer to about 800 degrees for about one minute in an oxygen-containing ambient. Layer 118 could be deposited instead.

Next a layer 120 of a silicide-forming metal is deposited. Preferred silicide-forming metals to be used for this purpose include titanium, cobalt, chromium, tantalum, platinum, nickel, niobium, and palladium. This example will describe the use of titanium for layer 120, but it will be understood that any of the other materials can be used.

Titanium layer 120 is deposited to any suitable thickness, for example between about 60 and about 200 angstroms, preferably between about 100 and about 150 angstroms, most preferably about 100 angstroms. To prevent oxidation of titanium layer 120, titanium nitride layer 122 is deposited, preferably about 300 angstroms thick. Layers 120 and 122 can be deposited by any conventional method, for example by sputtering.

An anneal is performed between about 600 and about 800 degrees from about 10 seconds to about two minutes, preferably between about 650 degrees and about 750 degrees, most preferably at about 670 degrees for about 20 seconds, for example in nitrogen. The anneal serves to reduce oxide layer 118 and to react titanium layer 120 with heavily doped regions 116 where it overlies them to form titanium silicide. Oxide layer 118 is substantially entirely reduced between titanium layer 120 and the silicon of heavily doped region 116. If oxide layer 118 was deposited rather than grown, the rest of oxide layer 118 (between the tops of semiconductor pillars 300, overlying dielectric fill 108) would remain. If oxide layer 118 was grown, it existed only in oxide regions 118 as shown in FIG. 2d.

As in a conventional salicide process, titanium nitride layer 122 and unreacted titanium are stripped in a selective wet etch, leaving behind titanium silicide layers 124, each formed in a disk-shaped region on the top of one of the junction diodes 30, shown in FIG. 2d.

Conventional salicide formation includes a second anneal following strip of the unreacted titanium to convert the titanium silicide from the high-resistivity C49 phase to the low-resistivity C54 phase. In embodiments of the present invention this step is omitted. It is known that this conversion is difficult to achieve when the area of titanium silicide is very small, as in titanium silicide layers 124. This conversion may not be necessary for the present use, and subsequent thermal processing, as additional memory levels are formed, may accomplish whatever phase conversion is achievable. In other embodiments a second anneal may be desirable.

As noted, in this example it is assumed that titanium is used in the silicide-forming metal layer 120, but other materials, including cobalt, chromium, tantalum, platinum, nickel, niobium, and palladium, could have been used instead. Thus titanium silicide layer 124 could instead be some other silicide, such as cobalt silicide, chromium silicide, tantalum silicide, platinum silicide, nickel silicide, niobium silicide, or palladium silicide.

At this point a plurality of first pillars has been formed above the first conductors, each pillar comprising a silicide layer.

Overlying conductors can be formed in the same manner as the underlying conductors. The overlying conductors will be formed at a height above the height of the first conductors, and extend in a different direction from them, preferably substantially perpendicular to them. Each memory cell comprises a portion of one of the first conductors, one of the first pillars, one of the dielectric rupture antifuses, and a portion of one of the second conductors. The resulting structure is a bottom or first level of memory cells. Additional memory levels can be monolithically formed above the first, as described in the '470 and '230 applications and the other incorporated references, forming a monolithic three dimensional memory array. For example, a second plurality of pillars can be formed above the upper conductors, and a third plurality of conductors can be formed above them. The upper conductors of one memory level can serve as the lower conductors of an overlying memory level, or an interlevel dielectric can be formed between them.

It will be noted that the first conductors were formed in a first pattern and etch step, the pillars were formed in a second pattern and etch step, and the second conductors were formed in a third pattern and etch step. The three pattern and etch steps are separate. Prior art three dimensional memories, such as the '882 patent, form analogous structures in pattern and etch steps that overlap.

The example just provided included formation of oxide layer 118 which was reduced during formation of titanium silicide layer 124. Forming and reducing this layer is preferred, but the step of reducing an oxide during silicide formation is not necessary in all embodiments to form a low-impedance junction diode.

Two diode configurations were shown in FIGS. 3a and 3b. In FIG. 3b, bottom region 112 is in situ doped with a p-type dopant such as boron. Boron atoms tend to promote crystallization of silicon during deposition, and in most conventional silicon deposition methods, silicon heavily in situ doped with boron will be polycrystalline as deposited. If the diode of FIG. 3b, for example, is used in the memory cells shown being fabricated in FIGS. 2a through 2d, it may be that some portion of the junction diode 300 will be crystalline before silicide layer 124 is formed. In this case, silicide layer 124 may not successfully provide a template to improve the crystallinity of the portions of the junction diode that are already crystallized. In preferred embodiments, the junction diode is amorphous silicon as deposited (as in the detailed example provided), and is crystallized in contact with a silicide. Note that if bottom region 112 is formed heavily doped with a p-type dopant in a way that allows it to be amorphous (doped by ion implantation, for example), it is expected that a low-impedance diode could be successfully created.

In the memory cell just described, as formed, the junction diode is conductive and is disposed between and is in electrical contact with the top and bottom conductors. Two layers are in electrical contact if no dielectric layers intervene, and a current can pass between them. Referring to FIG. 2d, titanium silicide layer 124 intervenes between heavily doped layer 116 at the top of each junction diode and the conductor above, and titanium nitride layer 110 intervenes between heavily doped layer 112 at the bottom of each junction diode. Both silicide layer 124 and titanium nitride layer 110 are good conductors, however, so each junction diode is in electrical contact with the conductors above and below.

The silicide layer is advantageous for reducing the impedance of the junction diode, but may not be desired in the finished device. In an alternative embodiment, following formation of the silicide layer on the junction diode, the silicide layer can be removed. The overlying conductors are then fabricated as usual.

The example given showed the silicide layer formed above the junction diode, but those skilled in the art will appreciate that the silicide layer can be formed elsewhere: beside the junction diode or below it, for example. Many configurations can be imagined.

The first embodiment of the present invention, just described, provides a remedy to a problem common to antifuse memories. An antifuse memory cell is read by applying a read voltage between the top and bottom conductors. If no current or only a very small current flows, the cell is unprogrammed; if a larger current flows, the cell is programmed. Repeated application of a read voltage to the same cell, however, can damage the antifuse, and the cumulative damage caused by many reading events may eventually unintentionally rupture it.

In the embodiment of the present invention just described, however, programming by destruction or disruption of the cell likely occurs by a thermal mechanism, occurring when the melting point of the silicon of the diode is reached. The melting point of the silicon of the diode will not be reached by application of a read voltage; thus no cumulative damage is caused to the cell no matter how many times it is read.

When this memory is complete, in the unprogrammed, low-impedance state, upon application of a read voltage between the first and second conductors of between about 0.5 and about 3 volts, a current of about 0.4 microamps or more, for example about 1.0 microamps or more, for example up to between about 50 and about 100 microamps, flows between the first and second conductors. In the programmed, high-impedance state, the resistance across the diode is about 1×10⁷ ohms or more, for example about 2×10⁸ ohms or more. The cell is programmed by a programming voltage preferably between about 4 and about 30 volts.

### Second Embodiment

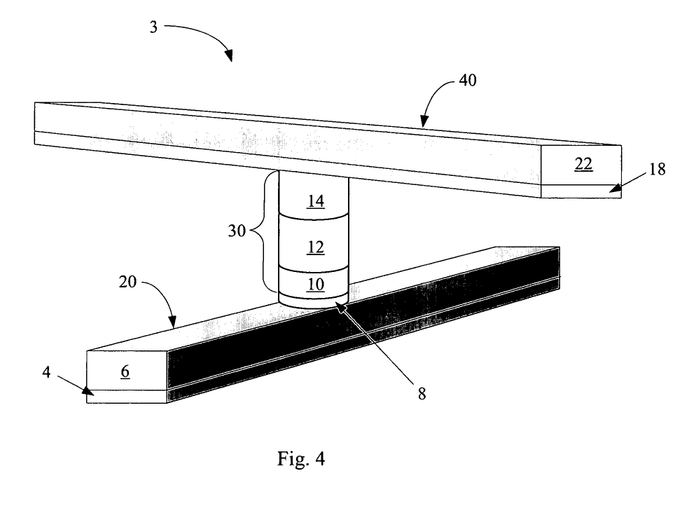

A second embodiment will also be described. In this embodiment a memory cell is formed as described in the ______ application (attorney docket no. MA-086-a-1), the cell having no dielectric antifuse and in a high-impedance state as formed. Such a memory cell 3 is shown in FIG. 4. A first conductor 20 preferably comprises titanium nitride layer 4 and tungsten layer 6. Junction diode 30 is formed on optional titanium nitride barrier layer 8 and comprises heavily doped semiconductor layer 10 of a first conductivity type, layer 12 which is undoped semiconductor material or lightly doped semiconductor material of a second conductivity type, and heavily doped semiconductor layer 14 of the second conductivity type. Second conductor 40 preferably comprises titanium nitride layer 18 and tungsten layer 22.

As formed, this cell is in an unprogrammed, high-impedance state, and, in the ______ application (attorney docket no. MA-086-a-1), the cell is converted to a programmed, low-impedance state by application of a programming voltage.

The present invention, however, is a fuse memory, in which an unprogrammed cell must be in a low-impedance state. In the present invention, a high impedance cell such as the cell of FIG. 4 is formed. It is then subjected to the voltage which, in the ______ application (attorney docket no. MA-086-a-1), is the programming voltage, converting it to a low-impedance state.

In the ______ application (attorney docket no. MA-086-a-1), this cell, now in a low-impedance state, was considered to be a programmed cell. In the present invention, however, this cell is considered to be an unprogrammed cell. At a later time, when the cell is to be programmed, a voltage sufficient to destroy or disrupt the diode is applied, converting the cell from an unprogrammed, low-impedance state to a programmed, high-impedance state. The diode serves as the fuse. In this case, the voltage that converted the cell as fabricated from its initial high-impedance state to the unprogrammed, low-impedance state is considered to be a preconditioning voltage (in the ______ application, the same voltage was considered to be a programming voltage.) The voltage that converts the cell from the unprogrammed, low-impedance state to a programmed, high-impedance state is considered the programming voltage.

A voltage is applied across the cell, producing a current. The current flowing through the diode actually induces the changes in the cell. Alternatively, then, it could be said that the current that converted the cell as fabricated from its initial high-impedance state to the unprogrammed, low-impedance state is considered a preconditioning current (in the ______ application (attorney docket no. MA-086-a-1), the same current acted as a programming current.) The current that converts the cell from the unprogrammed, low-impedance state to a programmed, high-impedance state is considered the programming current.

In general, the programming voltage will be greater than the preconditioning voltage. The preconditioning voltage, for example, would preferably be between about three and about eight volts, while the programming voltage would preferably be between about seven and about thirty volts.

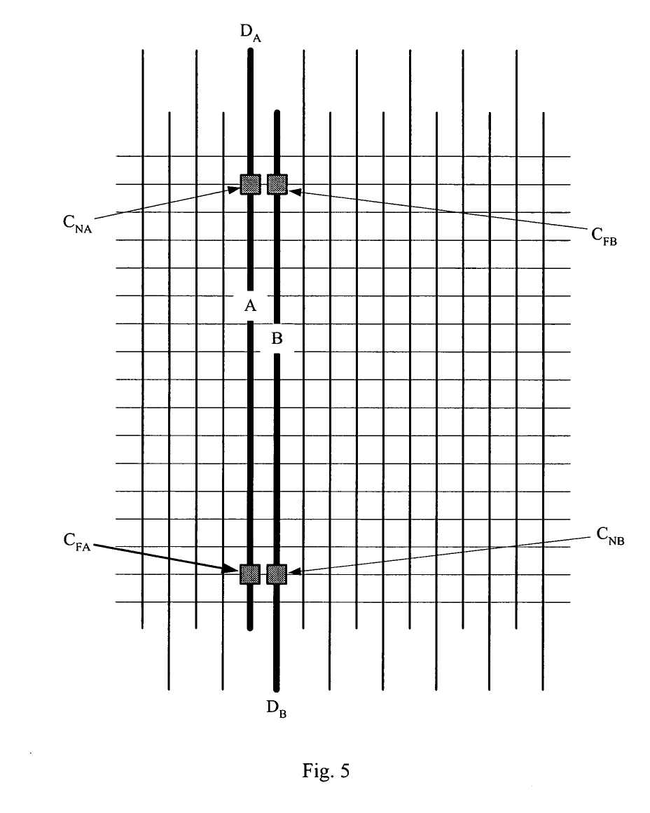

As has been described, cells are interposed between top and bottom conductors. FIG. 5 shows a plan view of one possible arrangement of a plurality of top conductors, which will here be called bitlines, and a plurality of bottom conductors, which will here be called wordlines. A driver is at one end of each bitline or wordline. It will be seen that the bitlines and wordlines are interleaved: driver D_{A} is at one end of bitline A, while driver D_{B} is at the opposite end of bitline B.

Memory cell C_{NA} on bitline A is a “near bit”, a cell that is relatively close to the driver D_{A} on that line. Memory cell C_{FA} on bitline A, which is relatively distant from the driver D_{A}, is a “far bit”. Similarly, memory cell C_{NB} is a near bit on bitline B, while memory cell C_{FB} is a far bit on bitline B. Because of its short distance from driver D_{A}, the resistance between near bit C_{NA} and driver D_{A} is relatively low, while the resistance between far bit C_{FA} and driver D_{A} is relatively high. It is more difficult to deliver a high current to far bit C_{FA} than it is to deliver a high current to near bit C_{NA}.

In a preferred embodiment, then, it may be advantageous to combine fuse and non-fuse memory cells in the same array. In this way the near bits can be programmed with a high voltage, while the far bits are programmed with a lower voltage.

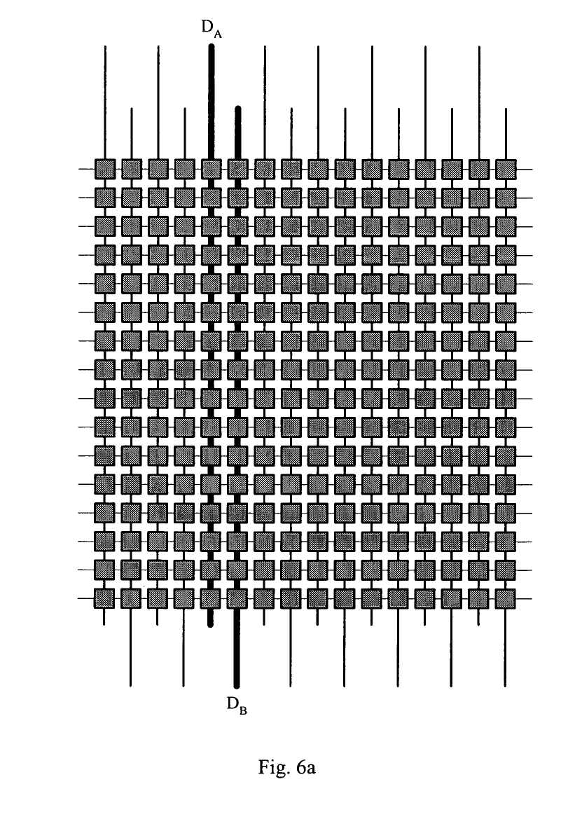

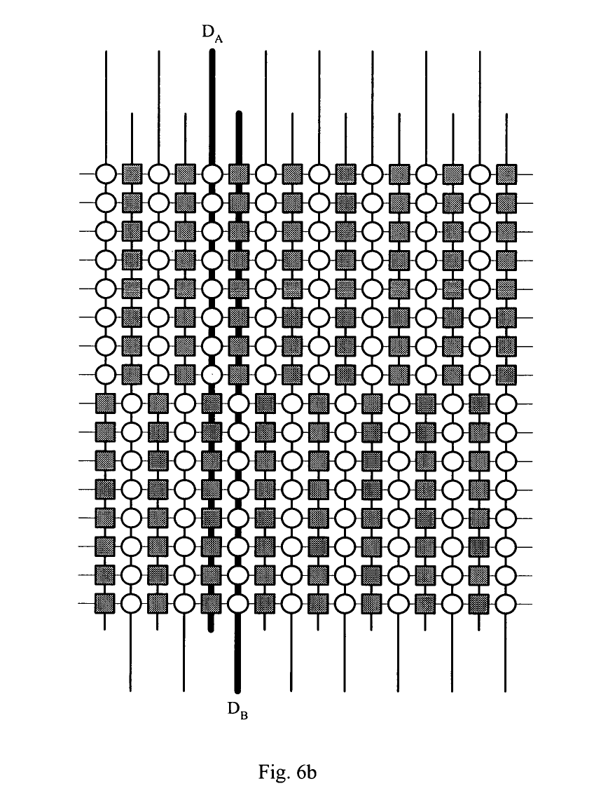

For example, an array of high-impedance cells like memory cell 3 of FIG. 4 can be formed. The array can be a monolithic three dimensional memory array, or could be a two-dimensional memory array. One memory level of such an array is shown in FIG. 6a. High-impedance cells are indicated by a shaded square. At this point, all of the cells are high-impedance cells.

Next the near bits on each bitline are subjected to a preconditioning voltage to convert them to a low-impedance state, indicated by a circle, shown in FIG. 6b. The far bits remain in the initial, high-impedance state. FIG. 6b shows an array of unprogrammed cells. The preconditioned low-impedance cells (indicated by circles) in FIG. 6b are fuse memory cells according to the present invention, which will become programmed when a programming voltage is applied, destroying or disrupting the diode and converting the cell to a high-impedance state. The non-preconditioned, high-impedance cells in FIG. 6b (indicated by squares) are not fuse memory cells, and will become programmed when a programming voltage is applied, converting each high-impedance cell to a low-impedance state. The programming voltage required to program the preconditioned fuse memory cells is greater than the programming voltage required to program the non-preconditioned memory cells. Thus a high programming voltage is required to program the near bits, where the higher voltage is easier to deliver, and a lower programming voltage is required to program the far bits, where this higher voltage is more difficult to deliver.

In this example the half of the bits nearer the driver on each line are considered near bits and are preconditioned to become low-impedance fuse memory cells, while the half more distant from the driver are considered far bits and remain high impedance, non-fuse memory cells. Clearly the dividing line between those cells that are preconditioned and those that are not need not be exactly half-way through the each bitline, and could be adjusted according to the actual voltages achievable at each point along each line. Further, for the sake of clarity, preconditioning was shown only along the bitline dimension. Far bits and near bits could be selectively preconditioned in the wordline direction as well.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, “Three dimensional structure memory.” The substrates may be thinned or removed from the memory levels before bonding, but as the memory levels are initially formed over separate substrates, such memories are not true monolithic three dimensional memory arrays.

The present invention has been described herein in the context of a monolithic three dimensional memory array formed above a substrate. Such an array comprises at least a first memory level formed at a first height above the substrate and a second memory level formed at a second height different from the first height. Three, four, up to eight or more memory levels can be formed above the substrate in such a multilevel array. Each memory level is monolithically formed on the memory level below it.

The memory cell of the present invention has been described as formed in a monolithic three dimensional memory array having stacked memory levels, but such cells could clearly be formed in a two-dimensional array, as well.

Detailed methods of fabrication have been described herein, but any other methods that form the same structures can be used while the results fall within the scope of the invention.

The foregoing detailed description has described only a few of the many forms that this invention can take. For this reason, this detailed description is intended by way of illustration, and not by way of limitation. It is only the following claims, including all equivalents, which are intended to define the scope of this invention.

What is claimed is:

1. A nonvolatile fuse memory cell having an unprogrammed and a programmed state, comprising a semiconductor junction diode, wherein the semiconductor junction diode operates as a fuse when the cell is converted from the unprogrammed state to the programmed state.

2. The nonvolatile fuse memory cell of claim 1 wherein, in the unprogrammed state, the semiconductor junction diode is in a low-impedance state, and in the programmed state, the semiconductor junction diode is in a high-impedance state.

3. The nonvolatile fuse memory cell of claim 2 further comprising a first conductor and a second conductor, wherein, in the unprogrammed state, the semiconductor junction diode is disposed between and is in electrical contact with the first and second conductors.

4. The nonvolatile fuse memory cell of claim 3 wherein, in the unprogrammed, low-impedance state, upon application of a read voltage between the first and second conductors of between about 0.5 and about 3 volts, a current of about 0.4 microamps or more flows between the first and second conductors.

5. The nonvolatile fuse memory cell of claim 4 wherein, in the unprogrammed, low-impedance state, upon application of a read voltage between the first and second conductors of between about 0.5 and about 3 volts, a current of about 1.0 microamps or more flows between the first and second conductors.

6. The nonvolatile fuse memory cell of claim 3 wherein, in the programmed, high-impedance state, the resistance across the diode is about 1×10⁷ ohms or more.

7. The nonvolatile fuse memory cell of claim 6 wherein, in the programmed, high-impedance state, the resistance across the diode is about 2×10⁸ ohms or more.

8. The nonvolatile fuse memory cell of claim 3 wherein the first conductor is formed at a first height above a substrate, the second conductor is formed at a second height above a substrate, the second height above the first, and the semiconductor junction diode is a vertically oriented pillar.

9. The nonvolatile fuse memory cell of claim 8 wherein the semiconductor junction diode is a p-i-n diode.

10. The nonvolatile fuse memory cell of claim 9 wherein, in the unprogrammed state, the semiconductor junction diode is in contact with a silicide layer.

11. The nonvolatile fuse memory cell of claim 10 wherein the silicide layer comprises a silicide selected from a group consisting of titanium silicide, cobalt silicide, chromium silicide, tantalum silicide, platinum silicide, nickel silicide, niobium silicide, and palladium silicide.

12. The nonvolatile fuse memory cell of claim 11 wherein the first conductor or the second conductor comprises tungsten.

13. The nonvolatile fuse memory cell of claim 11 wherein the maximum diameter of the semiconductor junction diode is no more than about 150 nm.

14. The nonvolatile fuse memory cell of claim 13 wherein the maximum diameter of the semiconductor junction diode is no more than about 90 nm.

15. The nonvolatile fuse memory cell of claim 8 wherein the substrate comprises monocrystalline silicon.

16. The nonvolatile fuse memory cell of claim 2 wherein the semiconductor junction diode is converted from the unprogrammed low-impedance state to the programmed high-impedance state by application of a programming voltage across the diode.

17. The nonvolatile fuse memory cell of claim 16 wherein the programming voltage is between about 4 and about 30 volts.

18. The nonvolatile fuse memory cell of claim 2 wherein the memory cell resides in a first memory level of a monolithic three dimensional memory array.

19. The nonvolatile fuse memory cell of claim 18 wherein at least a second memory level is monolithically formed above the first memory level.

20. A plurality of unprogrammed nonvolatile fuse memory cells comprising:
a plurality of substantially parallel first conductors formed at a first height above a substrate;
a plurality of substantially parallel second conductors formed at a second height above the substrate, wherein the second height is different from the first height;
a plurality of conductive pillars, each pillar disposed between one of the first conductors and one of the second conductors, and each pillar in electrical contact with one of the first pillars and one of the second pillars,
wherein each pillar comprises a silicide layer.

21. The plurality of unprogrammed nonvolatile fuse memory cells of claim 20 wherein each of the plurality of pillars comprises a semiconductor junction diode.

22. The plurality of unprogrammed nonvolatile fuse memory cells of claim 21 wherein each silicide layer is between and in contact with one of the semiconductor junction diodes and one of the second plurality of conductors.

23. The plurality of unprogrammed nonvolatile fuse memory cells of claim 22 wherein the second height is above the first height.

24. The plurality of unprogrammed nonvolatile fuse memory cells of claim 23 wherein each of the nonvolatile fuse memory cells comprises:
a portion of one of the plurality of first conductors;
one of the plurality of pillars; and
a portion of one of the plurality of second conductors.

25. The plurality of unprogrammed nonvolatile fuse memory cells of claim 24 wherein for each of the unprogrammed memory cells, upon application of a read voltage between the first conductor and the second conductor of a memory cell of between about 0.5 and about 3 volts, a current between about 0.4 and about 100 microamps flows between the first conductor and the second conductor of that memory cell.

26. The plurality of unprogrammed nonvolatile fuse memory cells of claim 25 wherein for each of the unprogrammed memory cells, upon application of a read voltage between the first conductor and the second conductor of a memory cell of between about 1.3 and about 2.3 volts, a current between about 1 and about 50 microamps flows between the first conductor and the second conductor of that memory cell.

27. The plurality of unprogrammed nonvolatile fuse memory cells of claim 20 wherein the silicide layer comprises a silicide selected from a group consisting of titanium silicide, cobalt silicide, chromium silicide, tantalum silicide, platinum silicide, nickel silcide, niobium silicide, and palladium silicide.

28. The plurality of unprogrammed nonvolatile fuse memory cells of claim 20 wherein the substrate comprises monocrystalline silicon.

29. The plurality of unprogrammed nonvolatile fuse memory cells of claim 20 wherein the plurality of cells make up a portion of a monolithic three dimensional memory array.

30. The plurality of unprogrammed nonvolatile fuse memory cells of claim 29 wherein the three dimensional monolithic memory array comprises at least two memory levels monolithically formed above one another.

31. A monolithic three dimensional memory array of memory cells, the array comprising:
a first memory level, the first memory level comprising a first plurality of memory cells, each memory cell of the first plurality having an unprogrammed and a programmed state, each memory cell comprising a semiconductor junction diode, wherein the semiconductor junction diode operates as a fuse when the cell is converted from the unprogrammed state to the programmed state; and
a second memory level, the second memory level monolithically formed above the first.

32. The monolithic three dimensional memory array of claim 31 wherein, in the unprogrammed state, each semiconductor junction diode is in a low-impedance state, and in the programmed state, each semiconductor junction diode is in a high-impedance state.

33. The monolithic three dimensional memory array of claim 32 further wherein the first memory level further comprises a plurality of first conductors formed at a first height above a substrate and a plurality of second conductors formed at a second height above the substrate, wherein the second height is different from the first.

34. The monolithic three dimensional memory array of claim 33 wherein each memory cell further comprising a portion of one of the first conductors and a portion of one of the second conductors, wherein, when the cell is in the unprogrammed state, the semiconductor junction diode is disposed between and is in electrical contact with the first and second conductor portions.

35. The monolithic three dimensional memory array of claim 34 wherein, in the unprogrammed, low-impedance state, upon application of a read voltage between the first and second conductors of each memory cell of between about 0.5 and about 3 volts, a current of about 0.4 amps or more flows between the first and second conductors of the memory cell.

36. The monolithic three dimensional memory array of claim 35 wherein, in the unprogrammed, low-impedance state, upon application of a read voltage between the first and second conductors of each memory cell of between about 0.5 and about 3 volts, a current of about 1.0 amps or more flows between the first and second conductors of the memory cell.

37. The monolithic three dimensional memory array of claim 32 wherein, in the programmed, high-impedance state, the resistance across each semiconductor junction diode is about 1×10⁷ ohms or more.

38. The monolithic three dimensional memory array of claim 32 wherein, in the programmed, high-impedance state, the resistance across each semiconductor junction diode is about 2×10⁸ ohms or more.

39. The monolithic three dimensional memory array of claim 32 wherein each semiconductor junction diode is a vertically oriented pillar.

40. The monolithic three dimensional memory array of claim 39 wherein each semiconductor junction diode is a p-i-n diode.

41. The monolithic three dimensional memory array of claim 40 wherein, in the unprogrammed state, each semiconductor junction diode is in contact with a silicide layer.

42. The monolithic three dimensional memory array of claim 41 wherein each silicide layer comprises a silicide selected from a group consisting of titanium silicide, cobalt silicide, chromium silicide, tantalum silicide, platinum suicide, nickel silicide, niobium silicide, and palladium silicide.

43. The monolithic three dimensional memory array of claim 32 wherein each semiconductor junction diode is converted from the unprogrammed low-impedance state to the programmed high-impedance state by application of a programming voltage across the diode.

44. The monolithic three dimensional memory array of claim 43 wherein the programming voltage is between about 4 and about 30 volts.

45. The monolithic three dimensional memory array of claim 31 wherein the first memory level further comprises a second plurality of memory cells, wherein the memory cells of the second plurality are not fuse memory cells.

46. The monolithic three dimensional memory array of claim 45 wherein each of the memory cells of the second plurality comprises a junction diode, the junction diode formed in an unprogrammed high-impedance state.

47. A monolithic three dimensional memory array comprising:
a first memory level formed above a substrate, the first memory level comprising:
a plurality of substantially parallel lower conductors formed at a first height above the substrate;
a plurality of substantially parallel upper conductors formed at a second height above the substrate, wherein the second height is above the first height; and
a plurality of pillars, each pillar disposed between one of the first conductors and one of the second conductors,
wherein each pillar comprises a junction diode and a silicide layer,
wherein each junction diode is in electrical contact with one of the lower conductors and one of the upper conductors;
and a second memory level monolithically formed above the first.

48. The monolithic three dimensional memory array of claim 47 wherein each silicide layer comprises a silicide selected from a group consisting of titanium silicide, cobalt silicide, chromium silicide, tantalum silicide, platinum silicide, nickel silicide, niobium silicide, and palladium silicide.

49. The monolithic three dimensional memory array of claim 48 wherein each silicide layer is between and in contact with one of the junction diodes and one of the conductors.

50. The monolithic three dimensional memory array of claim 49 wherein each silicide layer is between and in contact with one of the junction diodes and one of the upper conductors.

51. The monolithic three dimensional memory array of claim 47 wherein the substrate comprises monocrystalline silicon.

52. A method for forming and programming a fuse memory cell, the method comprising:
forming a memory cell, the memory cell comprising a semiconductor junction diode having an unprogrammed, low-impedance state; and
programming the memory cell by converting the diode to a programmed, high-impedance state.

53. The method of claim 52 wherein the step of forming the memory cell further comprises:
forming a first conductor at a first height above a substrate; and
forming a second conductor at a second height above the substrate, wherein the second height is above the first height,
wherein the semiconductor junction diode is disposed between the first and second conductors and is in electrical contact with the first and second conductors.

54. The method of claim 53 wherein the step of programming the memory cell comprises applying a programming voltage across the semiconductor junction diode.

55. The method of claim 54 wherein the programming voltage is between about 4 and about 30 volts.

56. The method of claim 54 wherein, in the unprogrammed, low-impedance state, upon application of a read voltage between the first and second conductors of between about 0.5 and about 3 volts, a current of about 0.4 amps or more flows between the first and second conductors.

57. The method of claim 56 wherein, in the unprogrammed, low-impedance state, upon application of a read voltage between the first and second conductors of between about 0.5 and about 3 volts, a current of about 1.0 amps or more flows between the first and second conductors.

58. The method of claim 54 wherein, in the programmed, high-impedance state, the resistance across the diode is about 1×10⁷ ohms or more.

59. The method of claim 58 wherein, in the programmed, high-impedance state, the resistivity across the diode is about 2×10⁸ ohms or more.

60. The method of claim 53 wherein the step of forming the memory cell further comprises forming the semiconductor junction diode by forming a p-i-n diode.

61. The method of claim 53 wherein the step of forming the memory cell further comprises forming the semiconductor junction diode by:
forming a first heavily doped silicon layer of a first conductivity type;
forming a second lightly or intrinsically doped silicon layer directly on the first heavily doped layer; and
forming a third heavily doped silicon layer of a second conductivity type directly on the second lightly or intrinsically doped silicon layer, the second conductivity type opposite the first.

62. The method of claim 53 wherein the first conductor is formed in a first patterning step, the semiconductor junction diode is formed in a second patterning step, and the second conductor is formed in a third patterning step, wherein each of the first, second, and third patterning steps is a separate step.

63. The method of claim 52 wherein the step of forming the memory cell comprises preconditioning the memory cell by applying a preconditioning voltage to place the semiconductor junction diode in the unprogrammed, low-impedance state.

64. The method of claim 63 wherein the step of programming the memory cell comprises applying a programming voltage to place the semiconductor junction diode in the programmed, high-impedance state.

65. The method of claim 64 wherein preconditioning voltage is less than the programming voltage.

66. The method of claim 65 wherein the preconditioning voltage is between about 3 and about 8 volts and the programming voltage is between about 7 and about 30 volts.

67. The method of claim 52 wherein the memory cell resides in a first memory level of a monolithic three dimensional memory array.

68. The method of claim 67 wherein at least a second memory level is monolithically formed above the first memory level.

69. A method for forming a plurality of unprogrammed fuse memory cells, the method comprising:
forming a plurality of substantially parallel first conductors at a first height above a substrate;
forming a plurality of first semiconductor junction diodes, each first semiconductor junction diode on and in electrical contact with one of the first conductors;
forming a silicide layer on and in contact with each of the first semiconductor junction diodes; and
forming a plurality of substantially parallel second conductors at a second height above the substrate, each silicide layer in electrical contact with one of the second conductors.

70. The method of claim 69 wherein the step of forming a silicide layer comprises:
forming an oxide region on each of the first semiconductor junction diodes;
depositing a silicide-forming metal on each oxide region; and
annealing to substantially entirely reduce each oxide region between the silicide-forming metal and the one of the first semiconductor junction diode and to form the silicide layer.

71. The method of claim 70 wherein the silicide-forming metal is selected from a group consisting of titanium, cobalt, chromium, tantalum, platinum, nickel, niobium, and palladium.

72. The method of claim 69 wherein the first conductors are formed in a first patterning step, the first semiconductor junction diodes are formed in a second patterning step, and the second conductors are formed in a third patterning step, wherein each of the first, second, and third patterning steps is a separate step.

73. The method of claim 69 wherein a plurality of second semiconductor junction diodes is formed above the second conductors.

74. The method of claim 73 wherein a plurality of third conductors is formed above the second semiconductor junction diodes.

75. A method for forming a monolithic three dimensional memory array, the method comprising:
forming a first memory level of memory cells by a method comprising:
forming a plurality of substantially parallel lower conductors at a first height above a substrate;
forming a plurality of substantially parallel upper conductors at a second height above the substrate, the second height above the first; and
forming a plurality of pillars, each pillar disposed between and in electrical contact with one of the first conductors and one of the second conductors,
wherein each pillar comprises a silicide layer;
and monolithically forming a second memory level above the first.

76. The method of claim 75 wherein each of the silicide layers comprises a silicide selected from a group consisting of titanium silicide, cobalt silicide, chromium silicide, tantalum silicide, platinum silicide, nickel silicide, niobium silicide, and palladium silicide.

77. The method of claim 76 wherein each pillar comprises a semiconductor junction diode.

78. The method of claim 77 wherein each silicide layer is formed by a method comprising:
forming an oxide region on each semiconductor junction diode;
depositing a silicide-forming metal on each oxide region; and
annealing to reduce the oxide region and to form the suicide layer.

79. The method of claim 75 wherein the step of forming the lower conductors comprises:
depositing a first conductive material;
patterning and etching the first conductive material to form the first conductors separated by first gaps;
filling the first gaps with a first dielectric material.

80. The method of claim 79 wherein the step of forming the pillars comprises:
depositing a semiconductor layer stack on the first conductors and first dielectric material;
patterning and etching the semiconductor layer stack to form the pillars.
